(19) United States
(12) Patent Application Publication
(10) Pub. No.: US 2015/0000738 A1
(43) Pub. Date: Jan. 1, 2015

(54) SOLAR CELL MODULE AND MAKING METHOD

(71) Applicant: SHIN-ETSU CHEMICAL CO., LTD., Tokyo (JP)

(72) Inventors: Atsuo Ito, Annaka-shi (JP); Tomoyoshi Furihata, Annaka-shi (JP); Hiroto Ohwada, Annaka-shi (JP); Hyung Bae Kim, Annaka-shi (JP); Atsushi Yaginuma, Annaka-shi (JP); Naoki Yamakawa, Annaka-shi (JP); Minoru Igarashi, Annaka-shi (JP); Masakatsu Hotta, Annaka-shi (JP); Tsutomu Nakamura, Annaka-shi (JP)

(73) Assignee: SHIN-ETSU CHEMICAL CO., LTD., Tokyo (JP)

(21) Appl. No.: 14/306,603

(22) Filed: Jun. 17, 2014

(30) Foreign Application Priority Data
Jun. 28, 2013 (JP) 2013-135864

(51) Int. Cl. H01L 31/048; H01L 31/20; H01L 31/18

(52) U.S. Cl. CPC H01L 31/0481; H01L 31/18; H01L 31/202
USPC 136/259; 438/64

(57) ABSTRACT

A solar cell module is provided comprising a first substrate (1a), a thin-film solar cell (2) comprising a metal electrode layer, a photoelectric conversion layer, and a light-transmissive electrode layer disposed on the first substrate (1a), a transparent second substrate (1b) opposed to the solar cell on the first substrate, a light-transmissive silicone gel layer (3) interposed between the first and second substrates, and a seal (4′) of a water vapor non-permeable, rubber-based thermoplastic sealing material surrounding the outer periphery of the silicone gel layer. The module has long-term reliability and high efficiency.

### CROSS-REFERENCE TO RELATED APPLICATION

This non-provisional application claims priority under 35 U.S.C. §119(a) on Patent Application No. 2013-135864 filed in Japan on Jun. 28, 2013, the entire contents of which are hereby incorporated by reference.

### TECHNICAL FIELD

This invention relates to a solar cell module and a method for manufacturing the same. More particularly, it relates to a solar cell module having encapsulated therein a thin-film silicon solar cell or thin-film solar cell using a photoelectric conversion layer of compound semiconductors such as chalcopyrite and chalcogen compound semiconductors, e.g., copper-indium-gallium-selenide (CIGS) or copper-indium-selenide (CIS), and chalcogen semiconductor materials composed of Cd, Zn, Te, S and Se.

### BACKGROUND ART

To provide solar cell modules with enhanced conversion efficiency and long-term reliability over 20 to 30 years or even longer, a number of reports and proposals relating to encapsulants were made in the art. From the standpoint of efficiency enhancement, silicone material is reported to be superior in internal quantum efficiency due to light transmittance at wavelength near 300 to 400 nm, as compared with the ethylene-vinyl acetate copolymer (EVA) which is currently the mainstream of encapsulant (see Non-Patent Document 1, for example). In fact, an experiment to compare the output power of solar modules using EVA and silicone material as encapsulant is reported (see Non-Patent Document 2, for example).

Originally, the use of silicone material as encapsulant was already implemented in the early period of 1970s when solar cell modules for spacecraft were fabricated. Historically, in the stage when solar cell modules for ground applications were manufactured, the silicone material was replaced by EVA because the silicone material had outstanding problems including material cost and workability for encapsulation whereas the EVA was inexpensive and supplied in film form. Recently, the efficiency enhancement and long-term reliability of solar cells are highlighted again. Accordingly, the properties of silicone material as encapsulant, for example, low modulus, high transparency and weather resistance are considered valuable again. Several encapsulating methods using silicone material are newly proposed.

For example, Patent Document 1 discloses encapsulation using a sheet of organopolysiloxane-based hot melt material. However, it is difficult to work the polysiloxane into a sheet while maintaining high transparency. When the polysiloxane is shaped into a sheet of about 1 mm thick, for example, only a particular shaping technique such as casting or pressing is applicable due to the “brittleness” of the material. This shaping technique is unsuitable for mass-scale production. To ameliorate the brittleness, a filler may be admixed with the polysiloxane. Filler loading can improve moldability at the sacrifice of transparency. Patent Document 2 discloses that interconnected solar cells are positioned on or in a liquid silicone material coated on a substrate, using a multi-axis robot. The liquid silicone material is then cured, thereby achieving encapsulation without trapping air bubbles. Further, Patent Document 3 proposes that a solar cell is placed on a cured or semi-cured silicone material in vacuum, and the components are compressed using a cell press having a movable plate, thereby achieving encapsulation without trapping air bubbles.

Patent Document 4 discloses a method of sealing a solar cell module by placing a sealing compound, a solar cell element, and a liquid silicone material on a glass substrate, then laying a back side protection substrate thereon to form a precursory laminate, and compression bonding the laminate in vacuum at room temperature. This method is applicable with difficulty to the manufacture of solar cell modules of practical size.

All the foregoing methods largely differ from the current sealing step using EVA in that they require the step of coating or placing a liquid silicone material before or after the step of sealing a solar cell. This is the main factor of inhibiting the use of cured silicone as sealing material in the solar cell module manufacture technology. Namely, unlike the prior art solar cell sealing method, the foregoing methods may not be viable with the existing mass production system.

Meanwhile, thin-film solar cells using a photoelectric conversion layer of chalcopyrite compound semiconductor are capable of efficiently converting the irradiated spectrum of sunlight into electricity, because the energy bandgap of a chalcopyrite semiconductor can be controlled from 1.01 eV to 1.64 eV by changing its composition. This complies with the desire to set the energy bandgap near 1.7 eV which is higher than the bandgap 1.14 eV of crystalline silicon. The thin-film solar cell using chalcopyrite compound semiconductor is regarded as having a higher capability of efficiently converting sunlight into electricity than the crystalline silicon solar cell. Furthermore, since the thin-film solar cell using chalcopyrite compound semiconductor has excellent light absorption characteristics, sufficient light absorption is possible even in thin film form. If a system that can form a thin film over a large area at a time is used, low cost production becomes possible. This technology is expected as the material technology enabling cost reduction.

Two factors for the solar cell are a conversion efficiency which indicates the percent conversion of incident sunlight into electricity and the cost of solar cell manufacture. In trial calculation of the cost of a solar cell, the cost per generated power (W) is handled as the expense (in dollar) per watt. When the solar cell is regarded as a power generation plant, it is required to have a long service life. Differently stated, the solar cell is required to undergo no or little degradation in power performance and minimal troubles over a long period of service. If a solar cell system has a twice longer lifetime, the cost of this system per unit power is reduced to ½.

The thin-film solar cell using chalcopyrite compound semiconductor is generally a stack of a metal electrode layer, a p-type CIS (copper-indium-selenide) layer, a high-resistance buffer layer, and a n-type window layer (having the function of a transparent electrode layer) deposited in sequence on a glass substrate, wherein the outermost surface of the stack becomes a light receiving surface. To protect the light receiving surface, a thermally toughened glass, commonly known as cover glass, is used. Using a thermoplastic resin, the cover glass is joined to the glass substrate such that the thin-film solar cell on the glass substrate is sandwiched inside, to complete a module.

Usually, ethylene-vinyl acetate (EVA) resins and polyvinyl butyral (PVB) resins are used as the thermoplastic resin, to which a crosslinker is added to impart strength. The joining step is followed by heat cure treatment. Specifically, a sheet of EVA or PVB composition is sandwiched between the cover glass and the light receiving surface of the compound semiconductor thin-film solar cell, and the assembly is heated in vacuum by means of a commercially available laminator. Owing to its thermoplastic nature, the sheet is melted and bonded to the cover glass and glass substrate to complete a module.

However, EVA is susceptible to hydrolysis in an acidic or alkaline environment, generating acetic acid. It is pointed out that acetic acid can attack the metal electrode at the contact interface with the solar cell. Not only hydrolysis causes corrosion of the metal electrode, but also decomposition of EVA itself incurs a lowering of bond strength at the bonding interface, and at worst, separation known as delamination can occur. It is noted that the occurrence of hydrolysis can be predicted by applying an accelerated stress in a high temperature/high humidity environment. The application of accelerated stress in a high temperature/high humidity environment is typically exposure to an environment of 85° C. and relative humidity 85% for 1,000 hours and 2,000 hours. In such an environment, the EVA resin usually undergoes decomposition to release acetic acid. The tank for the accelerated stress environment test becomes full of acetic acid odor.

On the other hand, it is known that due to its thermoplastic nature, the EVA resin increases its modulus at lower temperature and decreases its modulus at higher temperature. Thus, as a result of temperature changes in the environmental and weather conditions under which the solar cell module is installed, repetitive stresses are applied to the contact layer at the outermost surface of the solar cell. The degradation of the solar cell by such stresses manifests itself as separation of the current collector electrode pattern, typically finger electrode and bus bar electrode, in the crystalline silicon solar cell module.

Like the crystalline silicon solar cell, similar improvements in long-term reliability are desired for the thin-film solar cell based on chalcopyrite compound semiconductor and used under the same environment, because ingress of water can cause increased resistance of Al-doped ZnO transparent conductive film and corrosion of Al/Ni collector electrode (see Non-Patent Document 3).

Also, a UV absorber is added to the EVA resin for the purpose of suppressing photo-degradation of the resin upon exposure to light of short wavelength 400 nm or less. This inhibits a sunlight component having a wavelength of 400 nm or less from entering the photoelectric conversion layer of the solar cell. For the thin-film solar cell using chalcopyrite compound semiconductor having a wider bandgap and an optimum sensitivity to light of shorter wavelength than the crystalline silicon solar cell, an encapsulating material transmissive to light of short wavelength 400 nm or less is demanded as the replacement for EVA.

Silicone resin is typical of the transparent material capable of protecting the outermost surface of a solar cell, maintaining a low modulus against severe temperature changes in an outdoor environment, and affording high durability under UV exposure. The silicone resin is generally supplied as a two-part composition of addition cure type and used as a liquid encapsulating material. When the silicone resin is used in forming a module of crystalline silicon solar cells, one typical procedure involves forming a frame of end-face sealing material along the periphery of a glass plate, casting the silicone composition inside, resting a solar cell thereon, casting the silicone composition thereon again to bury the solar cell, and heat curing the silicone composition. In an alternative known procedure, a silicone resin composition is coated to two glass plates, a string of silicon solar cells is sandwiched therebetween in vacuum, and the silicone composition is heat cured.

However, it is difficult to dispense the silicone composition in vacuum without generating air bubbles in the frame of peripheral material. Also, the procedure of coating the silicone composition, joining the two coated plates together and curing the silicone composition has the problem associated with the low viscosity of the silicone composition that if the coated surfaces are vertically directed, the silicone coating will flow downward, and such flow invites variations in the coating thickness. If the coated surfaces are vertically directed after the coatings are cured, any flow can be inhibited, but there arises another problem that once the silicone composition is cured, no bond is established when the two plates are mated together. It is thus eventually required to dispense the silicone composition in vacuum.

Because of such cumbersome steps, the application of silicone material featuring a low modulus to the mass production of crystalline silicone solar cells has not been implemented.

### CITATION LIST

Patent Document 1: JP-A 2009-515365 (US 20080276983)
Patent Document 2: JP-A 2007-527109 (US 20060207646)
Patent Document 3: JP-A 2011-514680 (US 20110061724)
Patent Document 4: WO 2009/091068
Non-Patent Document 1: S. Ohl, G. Hahn, “Increased internal quantum efficiency of encapsulated solar cell by using two-component silicone as encapsulant material”, Proc. 23rd, EU PVSEC, Valencia (2008), pp. 2693-2697
Non-Patent Document 2: Barry Ketola, Chris Shirk, Phillip Griffith, Gabriela Bunea, “Demonstration of the benefits of silicone encapsulation of PV modules in a large scale outdoor array”, Dow Corning Corporation
Non-Patent Document 3: “Fundamentals of Thin-Film Solar Cell,” the Photovoltaic Power Generation Technology Research Association, Ed. M. Konagai, 2001

### DISCLOSURE OF INVENTION

An object of the invention is to provide a solar cell module which contributes to long-term reliability and high efficiency of a thin-film solar cell module having a photoelectric conversion layer of chalcopyrite compound semiconductor, overcomes the above-discussed process problems, and is sealed with a silicone resin amenable to mass-scale production. Another object is to provide a method for manufacturing the solar cell module.

The invention provides a solar cell module and a manufacturing method as defined below.

[1] A solar cell module comprising

a first substrate having a surface,

a thin-film solar cell comprising a metal electrode layer, a photoelectric conversion layer, and a light-transmissive electrode layer disposed on the surface of the first substrate in the described order,

a transparent second substrate disposed above the surface of the first substrate,

a light-transmissive silicone gel layer interposed between the first and second substrates so as to overlap the thin-film solar cell, and

a seal portion comprising a water vapor non-permeable, rubber-based thermoplastic sealing material surrounding and sealing the outer periphery of the silicone gel layer.

[2] A solar cell module comprising

a transparent first substrate having a surface,

a thin-film solar cell comprising a light-transmissive electrode layer, a photoelectric conversion layer, and a metal electrode layer disposed on the surface of the first substrate in the described order,

a second substrate disposed above the surface of the first substrate,

a silicone gel layer interposed between the first and second substrates so as to overlap the thin-film solar cell, and

a seal portion comprising a water vapor non-permeable, rubber-based thermoplastic sealing material surrounding and sealing the outer periphery of the silicone gel layer.

[3] The solar cell module of [1] or [2] wherein the rubber-based thermoplastic sealing material is butyl rubber.
[4] The solar cell module of any one of [1] to [3] wherein the photoelectric conversion layer comprises a chalcopyrite compound semiconductor.
[5] The solar cell module of any one of [1] to [3] wherein the photoelectric conversion layer comprises a chalcogen compound semiconductor.
[6] The solar cell module of any one of [1] to [3] wherein the photoelectric conversion layer is an amorphous silicon layer.
[7] The solar cell module of any one of [1] to [3] wherein the photoelectric conversion layer is a microcrystalline thin-film silicon layer.
[8] The solar cell module of any one of [1] to [3] wherein the photoelectric conversion layer is a germanium-containing thin-film layer.
[9] A method for manufacturing a solar cell module comprising the steps of:

(i) stacking a metal electrode layer, a photoelectric conversion layer, and a light-transmissive electrode layer on one surface of a first substrate, excluding a peripheral region of the one surface, in the described order to construct a thin-film solar cell,

(ii) forming a light-transmissive silicone gel layer on one surface of a transparent second substrate, excluding a peripheral region of the one surface,

(iii) mating the first and second substrates together such that the thin-film solar cell-bearing surface of the first substrate may be opposed to the silicone gel layer-bearing surface of the second substrate, and the silicone gel layer may overlap the thin-film solar cell, while interposing a seal member between the peripheral region of the first substrate where the thin-film solar cell is not formed and the peripheral region of the second substrate where the silicone gel layer is not formed, the seal member comprising a water vapor non-permeable, rubber-based thermoplastic sealing material and being thicker than the silicone gel layer, and

(iv) compressing and heating the first and/or second substrate in the mated state for establishing a seal around the thin-film solar cell.

[10] A method for manufacturing a solar cell module comprising the steps of:

(i) stacking a metal electrode layer, a photoelectric conversion layer, and a light-transmissive electrode layer on one surface of a first substrate, excluding a peripheral region of the one surface, in the described order to construct a thin-film solar cell,

(ii) providing a transparent second substrate having a surface and a light-transmissive silicone gel sheet which is smaller than the surface of the second substrate and larger than the thin-film solar cell,

(iii) mating the first and second substrates together while placing the silicone gel sheet between the thin-film solar cell-bearing surface of the first substrate and the surface of the second substrate and above the thin-film solar cell, and placing a seal member between the peripheral region of the first substrate where the thin-film solar cell is not formed and a peripheral region of the second substrate which does not overlap the silicone gel sheet, the seal member comprising a water vapor non-permeable, rubber-based thermoplastic sealing material and being thicker than the silicone gel sheet, and

(iv) compressing and heating the first and/or second substrate in the mated state for establishing a seal around the thin-film solar cell.

[11] A method for manufacturing a solar cell module comprising the steps of:

(i) stacking a light-transmissive electrode layer, a photoelectric conversion layer, and a metal electrode layer on one surface of a transparent first substrate, excluding a peripheral region of the one surface, in the described order to construct a thin-film solar cell,

(ii) forming a silicone gel layer on one surface of a second substrate, excluding a peripheral region of the one surface,

(iii) mating the first and second substrates together such that the thin-film solar cell-bearing surface of the first substrate may be opposed to the silicone gel layer-bearing surface of the second substrate, and the silicone gel layer may overlap the thin-film solar cell, while interposing a seal member between the peripheral region of the first substrate where the thin-film solar cell is not formed and the peripheral region of the second substrate where the silicone gel layer is not formed, the seal member comprising a water vapor non-permeable, rubber-based thermoplastic sealing material and being thicker than the silicone gel layer, and

(iv) compressing and heating the first and/or second substrate in the mated state for establishing a seal around the thin-film solar cell.

[12] A method for manufacturing a solar cell module comprising the steps of:

(i) stacking a light-transmissive electrode layer, a photoelectric conversion layer, and a metal electrode layer on one surface of a transparent first substrate, excluding a peripheral region of the one surface, in the described order to construct a thin-film solar cell,

(ii) providing a second substrate having a surface and a silicone gel sheet which is smaller than the surface of the second substrate and larger than the thin-film solar cell,

(iii) mating the first and second substrates together while placing the silicone gel sheet between the thin-film solar cell-bearing surface of the first substrate and the surface of the second substrate and above the thin-film solar cell, and placing a seal member between the peripheral region of the first substrate where the thin-film solar cell is not formed and a peripheral region of the second substrate which does not overlap the silicone gel sheet, the seal member comprising a water vapor non-permeable, rubber-based thermoplastic sealing material and being thicker than the silicone gel sheet, and

(iv) compressing and heating the first and/or second substrate in the mated state for completing a seal around the thin-film solar cell.

[13] The method of [9] or [11] wherein step (i) includes applying a curable silicone gel composition on the one surface of the second substrate and curing it to form a silicone gel layer.
[14] The method of [10] or [12] wherein step (iii) includes attaching the preformed silicone gel sheet to the second substrate, prior to the mating of the first and second substrates.
[15] The method of any one of [9] to [14] wherein the seal member is made of butyl rubber.
[16] The method of any one of [9] to [15] wherein step (iv) includes placing the mated first and second substrates in a space, evacuating the space to vacuum, and heating and compressing the first and second substrates in vacuum for establishing a seal around the thin-film solar cell.

### Advantageous Effects of Invention

Intending to optimize the method of sealing thin-film solar cells with encapsulant material, the invention contributes to the long-term reliability and high efficiency of a solar cell module. Since the silicone composition can be coated and cured in air without a need for dispensing in vacuum, module formation using a conventional laminator is possible. The invention is not limited to thin-film solar cells having a photoelectric conversion layer of chalcopyrite compound semiconductor, but applicable to those cells having a chalcogen compound semiconductor layer, amorphous silicon layer, microcrystalline thin-film silicon layer, and germanium-containing thin-film layer.

### BRIEF DESCRIPTION OF DRAWINGS

FIG. 1 is a cross-sectional view of one panel on which a thin-film solar cell is formed.

FIG. 2 is a cross-sectional view of another panel on which a silicone gel layer is formed.

FIG. 3 is a cross-sectional view of the other panel on which a seal member is provided on a peripheral region of the silicone gel layer-bearing surface.

FIG. 4 is a cross-sectional view of a stack of the panels with the thin-film solar cell-bearing surface of one panel being opposed to the silicone gel layer-bearing surface of the other panel.

FIG. 5 is a cross-sectional view of a solar cell module sealed by the laminating step using a vacuum laminator.

### DESCRIPTION OF PREFERRED EMBODIMENTS

In the following description, like reference characters designate like or corresponding parts throughout the several views shown in the figures. The terms “first”, “second”, and the like, as used herein do not denote any order, quantity, or importance, but rather are used to distinguish one element from another. It is also understood that terms such as “above,” “below,” “outward,” “inward,” and the like are words of convenience and are not to be construed as limiting terms.

The solar cell module and manufacturing method of the invention are described with reference to several preferred embodiments.

### First Embodiment

A first embodiment of the invention is a solar cell module comprising a first substrate having a surface, a thin-film solar cell comprising a metal electrode layer, a photoelectric conversion layer, and a light-transmissive electrode layer disposed on the surface of the first substrate in the described order, a transparent second substrate disposed above the surface of the first substrate, a light-transmissive silicone gel layer interposed between the first and second substrates so as to overlap the thin-film solar cell, and a seal portion comprising a water vapor non-permeable, rubber-based thermoplastic sealing material surrounding and sealing the outer periphery of the silicone gel layer.

A method for manufacturing the solar cell module of the first embodiment is defined as comprising the steps of:

(i) stacking a metal electrode layer, a photoelectric conversion layer, and a light-transmissive electrode layer on one surface of a first substrate, excluding a peripheral region of the one surface, in the described order to construct a thin-film solar cell,

(ii) forming a light-transmissive silicone gel layer on one surface of a transparent second substrate, excluding a peripheral region of the one surface,

(iii) mating the first and second substrates together such that the thin-film solar cell-bearing surface of the first substrate may be opposed to the silicone gel layer-bearing surface of the second substrate, and the silicone gel layer may overlap the thin-film solar cell, while interposing a seal member between the peripheral region of the first substrate where the thin-film solar cell is not formed and the peripheral region of the second substrate where the silicone gel layer is not formed, the seal member comprising a water vapor non-permeable, rubber-based thermoplastic sealing material and being thicker than the silicone gel layer, and

(iv) compressing and heating the first and/or second substrate in the mated state for establishing a seal around the thin-film solar cell.

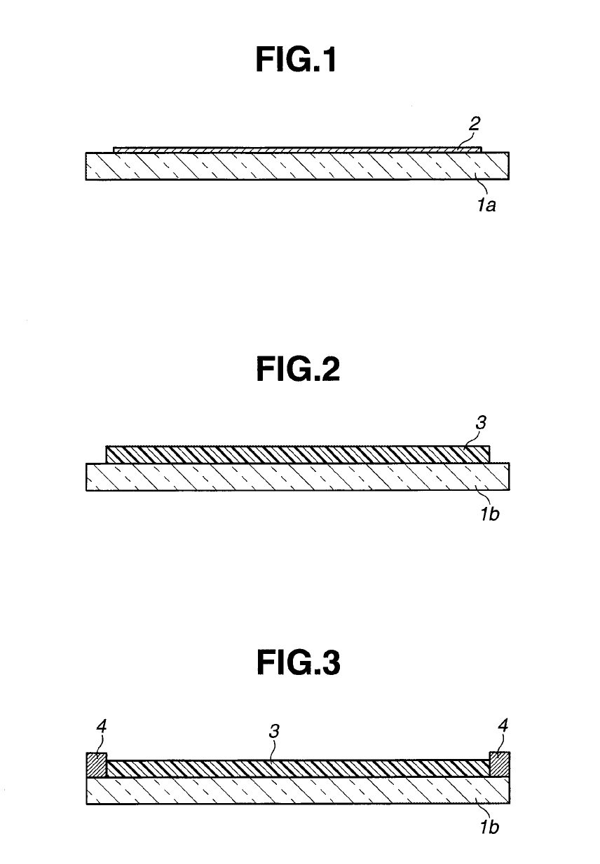

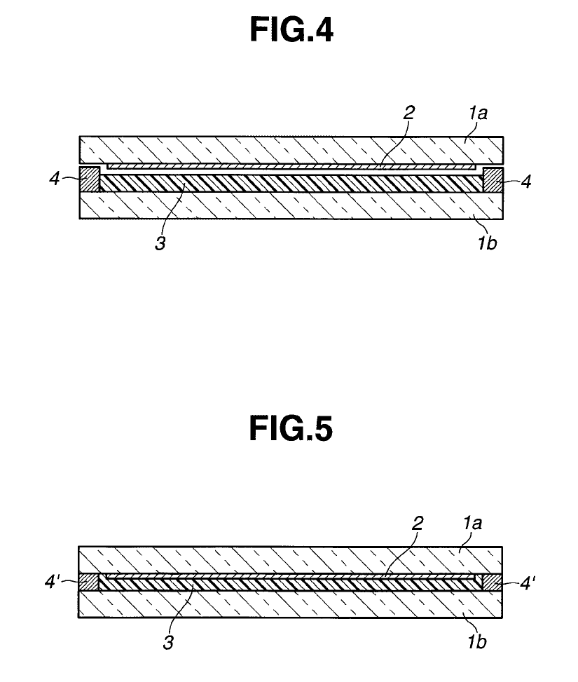

Referring to FIGS. 1 to 5, the first embodiment of the invention is described in detail. FIG. 1 illustrates in cross section an exemplary thin-film solar cell formed on one panel. FIG. 2 illustrates in cross section an exemplary silicone gel layer formed on another panel. FIG. 3 illustrates in cross section a seal member provided on an outer peripheral region of the silicone gel layer-bearing surface of the other panel. FIG. 4 illustrates the thin-film solar cell-bearing one panel placed above the other panel of FIG. 3. FIG. 5 illustrates the two panels of FIG. 4 after vacuum laminating step.

### (i) Step of Forming Thin-Film Solar Cell (FIG. 1)

First of all, as shown in FIG. 1, a metal electrode layer, a photoelectric conversion layer, and a light-transmissive electrode layer are stacked on one surface of one panel 1a, excluding a peripheral region of the one surface, in the described order to construct a thin-film solar cell 2.

One panel 1a corresponds to the first substrate in the first embodiment, serves as a panel remote from the sunlight incident side, and must provide efficient heat dissipation of the temperature of the solar cell. It may be made of glass materials, synthetic resins, metals and composite materials thereof. Suitable glass materials include soda-lime glass, colorless glass, and strengthened glass. Suitable synthetic resins include acrylic resins, polycarbonate (PC) resins, polyethylene terephthalate (PET) resins, and epoxy resins. Suitable metals include copper, aluminum, and iron. Suitable composite materials include synthetic resins filled with high heat conductivity agents such as silica, titania, alumina and aluminum nitride.

If one panel 1a disposed remote from the sunlight-incident side is a transparent member like another panel 1b on which sunlight is incident, the solar cell is of see-through type so that parts of incident sunlight and scattering light may be transmitted to the remote side. Then in an example where the solar cell module is installed in a grassland, part of sunlight reaches the area of the land which is disposed below and shaded by the module, so that plants can grow even in the otherwise shaded area. This is convenient in that the module-installed region can also be utilized for pasturage.

Typical of the thin-film solar cell 2 formed on one panel 1a is a chalcopyrite compound semiconductor thin-film solar cell. In this case, the metal electrode layer is a Mo layer deposited by DC magnetron sputtering. The photoelectric conversion layer includes a p-type light-absorbing layer of chalcopyrite compound semiconductor such as copper-indium-gallium-selenide (CIGS) or copper-indium-selenide (CIS), and an n-type high-resistivity buffer layer of CdS formed thereon. The p-type light-absorbing layer may be formed by the three-stage evaporation method, and the n-type high-resistivity buffer layer be formed by the solution growth method. The light-transmissive electrode layer is a ZnO-based transparent conductive film window layer which is formed by sputtering.

Instead of the CIGS chalcopyrite semiconductor layer, there may be used a compound semiconductor layer consisting of a chalcopyrite semiconductor layer and a chalcogen semiconductor layer composed of such constituent elements as Cd, Zn, Te, S and Se, as partial replacement.

When panel 1a is a substrate of soda-lime glass, its thickness is preferably about 1.8 mm in view of strength. As to the thickness of the constituent layers, for example, the electrode layer in the form of Mo deposited layer has a thickness of 0.8 μm, the p-type light-absorbing layer of CuInGaSe₂ has a thickness of 1.7 μm, the n-type high-resistivity buffer layer of CdS has a thickness of 50 nm, the ZnO semi-insulating layer has a thickness of 0.1 μm, and the transparent conductive film window layer has a thickness of 0.6 μm. In addition, a surface antireflective layer in the form of MgF₂ layer thereon has a thickness of 120 nm, and the interdigitated electrode of Ag has a thickness of 0.6 μm.

Also included are thin-film solar cells having an amorphous silicon layer, microcrystalline thin-film silicon layer, or germanium-containing thin-film layer as the photoelectric conversion layer. For example, the invention is applicable to a thin-film silicon solar cell comprising an electrode layer, thin-film silicon semiconductor layer, transparent electrode layer, and extracting electrode layer formed on a substrate (panel 1a) in the described order.

### (ii) Step of Forming Silicone Gel Layer (FIG. 2)

Next, as shown in FIG. 2, a silicone gel layer 3 is formed on one surface of another panel 1b in the form of a transparent member by coating and curing a curable silicone gel composition thereto.

The other panel 1b is a transparent member on the sunlight incident side. A member having transparency, weather resistance, impact resistance and long-term reliable performance during outdoor service is necessary. For example, members of strengthened colorless glass, acrylic resins, fluoro-resins or polycarbonate resins are useful, with strengthened colorless glass plates having a thickness of about 3 to 5 mm being preferred.

The silicone gel layer 3 must have transparency, weather resistance, and long-term reliability during outdoor service over 20 years. To this end, the silicone gel layer 3 must have high UV resistance, low modulus, and good bond to the panels 1a, 1b.

The silicone gel layer 3 may be formed of a curable silicone gel composition. The crosslinking mode of the composition may be any of moisture cure, UV cure, organic peroxide cure, and addition cure with platinum catalyst. Of these, the addition cure type silicone composition is preferred because of no by-product formation and little discoloring.

The curable silicone gel composition used herein is preferably defined as comprising the following components:

(A) 100 parts by weight of an organopolysiloxane containing at least one silicon-bonded alkenyl group per molecule, represented by the average compositional formula (1):

RₐR¹_{b}SiO_{(4-a-b)/2} (1)

wherein R is independently alkenyl, R¹ is independently a substituted or unsubstituted monovalent hydrocarbon group of 1 to 10 carbon atoms free of aliphatic unsaturation, a is a positive number of 0.0001 to 0.2, b is a positive number of 1.7 to 2.2, and the sum a+b is 1.9 to 2.4,

(B) an organohydrogenpolysiloxane containing at least two silicon-bonded hydrogen atoms per molecule, in such an amount as to give 0.3 to 2.5 moles of silicon-bonded hydrogen per mole of silicon-bonded alkenyl in component (A), and

(C) a catalytic amount of an addition reaction catalyst.

Component (A) serves as a base polymer in the curable silicone gel composition. It is an organopolysiloxane containing at least one silicon-bonded alkenyl group per molecule, represented by the average compositional formula (1).

In formula (1), R is independently an alkenyl group of 2 to 6 carbon atoms, preferably 2 to 4 carbon atoms, and more preferably 2 to 3 carbon atoms. Examples include vinyl, allyl, propenyl, isopropenyl, butenyl, and isobutenyl, with vinyl being most preferred.

R¹ is independently a substituted or unsubstituted monovalent hydrocarbon group free of aliphatic unsaturation, having 1 to 10 carbon atoms, preferably 1 to 6 carbon atoms. Examples of the monovalent hydrocarbon group include straight, branched or cyclic alkyl groups such as methyl, ethyl, propyl, isopropyl, butyl, isobutyl, tert-butyl, pentyl, hexyl, cyclohexyl, octyl and decyl; aryl groups such as phenyl and tolyl; aralkyl groups such as benzyl and phenylethyl; and substituted forms of the foregoing in which some or all hydrogen atoms are substituted by halogen (e.g., chloro, bromo or fluoro) such as chloromethyl and 3,3,3-trifluoropropyl. Of these, methyl, phenyl and 3,3,3-trifluoropropyl are preferred for ease of synthesis. Inter alia, methyl is most preferred in view of UV resistance.

The subscript “a” is a positive number of 0.0001 to 0.2, preferably 0.0005 to 0.1; b is a positive number of 1.7 to 2.2, preferably 1.9 to 2.02. The sum a+b is in a range from 1.9 to 2.4, preferably from 1.95 to 2.05.

The organopolysiloxane should contain at least one silicon-bonded alkenyl group per molecule, preferably at least two, more preferably 2 to 50, and even more preferably 2 to 10 silicon-bonded alkenyl groups per molecule. The values of a and b may be selected so as to meet the requirement of silicon-bonded alkenyl group.

The molecular structure of the organopolysiloxane is not particularly limited. It may have a linear structure or a branched structure containing such units as RSiO_{3/2}, R¹SiO_{3/2}, and SiO₂ units wherein R and R¹ are as defined above.

Preferred is an organopolysiloxane having the general formula (1a), that is, a substantially linear diorganopolysiloxane having a backbone consisting essentially of recurring diorganosiloxane units and terminated with a triorganosiloxy group at either end of the molecular chain.

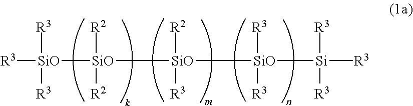

Herein R² is independently a substituted or unsubstituted monovalent hydrocarbon group free of aliphatic unsaturation; R³ is independently a substituted or unsubstituted monovalent hydrocarbon group free of aliphatic unsaturation or an alkenyl group, with the proviso that at least one R³ is alkenyl; where either one of R³ at opposite ends of the molecular chain is alkenyl, k is an integer of 40 to 1,200, m is an integer of 0 to 50, and n is an integer of 0 to 50; where none of R³ at opposite ends of the molecular chain are alkenyl, k is an integer of 40 to 1,200, m is an integer of 1 to 50, and n is an integer of 0 to 50; and the sum m+n is at least 1.

In formula (1a), R² is independently a substituted or unsubstituted monovalent hydrocarbon group free of aliphatic unsaturation, having 1 to 10 carbon atoms, preferably 1 to 6 carbon atoms. Examples are as exemplified for R¹ in formula (1). Inter alia, methyl, phenyl and 3,3,3-trifluoropropyl are preferred for ease of synthesis.

Also R³ is independently a substituted or unsubstituted monovalent hydrocarbon group free of aliphatic unsaturation, having 1 to 10 carbon atoms, preferably 1 to 6 carbon atoms. Examples are as exemplified for R¹ in formula (1). Inter alia, methyl, phenyl and 3,3,3-trifluoropropyl are preferred for ease of synthesis. Alternatively, R³ is an alkenyl group of 2 to 6 carbon atoms, preferably 2 to 4 carbon atoms, and more preferably 2 to 3 carbon atoms. Examples include vinyl, allyl, propenyl, isopropenyl, butenyl, and isobutenyl, with vinyl being most preferred.

In formula (1a), where either one of R³ at opposite ends of the molecular chain is alkenyl, preferably k is an integer of 100 to 1,000, m is an integer of 0 to 40, and n is 0. Where none of R³ at opposite ends of the molecular chain are alkenyl, preferably k is an integer of 100 to 1,000, m is an integer of 2 to 40, and n is 0.

Examples of the organopolysiloxane of formula (1a) include, but are not limited to,

both end dimethylvinylsiloxy-terminated dimethylpolysiloxane,
both end dimethylvinylsiloxy-terminated dimethylsiloxane/methylvinylsiloxane copolymers,
both end dimethylvinylsiloxy-terminated dimethylsiloxane/diphenylsiloxane copolymers,
both end dimethylvinylsiloxy-terminated dimethylsiloxane/methylvinylsiloxane/diphenylsiloxane copolymers,
both end dimethylvinylsiloxy-terminated methyltrifluoropropylpolysiloxane,
both end dimethylvinylsiloxy-terminated dimethylsiloxane/methyltrifluoropropylsiloxane copolymers,
both end dimethylvinylsiloxy-terminated dimethylsiloxane/methyltrifluoropropylsiloxane/methylvinylsiloxane copolymers,
both end trimethylsiloxy-terminated dimethylsiloxane/vinylmethylsiloxane copolymers,
both end trimethylsiloxy-terminated dimethylsiloxane/vinylmethylsiloxane/diphenylsiloxane copolymers,
both end trimethylsiloxy-terminated vinylmethylsiloxane/methyltrifluoropropylsiloxane copolymers, trimethylsiloxy and dimethylvinylsiloxy-terminated dimethylpolysiloxane,
trimethylsiloxy and dimethylvinylsiloxy-terminated dimethylsiloxane/methylvinylsiloxane copolymers,
trimethylsiloxy and dimethylvinylsiloxy-terminated dimethylsiloxane/diphenylsiloxane copolymers,
trimethylsiloxy and dimethylvinylsiloxy-terminated dimethylsiloxane/diphenylsiloxane/methylvinylsiloxane copolymers,
trimethylsiloxy and dimethylvinylsiloxy-terminated methyltrifluoropropylpolysiloxane,
trimethylsiloxy and dimethylvinylsiloxy-terminated dimethylsiloxane/methyltrifluoropropylsiloxane copolymers, trimethylsiloxy and dimethylvinylsiloxy-terminated dimethylsiloxane/methyltrifluoropropylsiloxane/methylvinylsiloxane copolymers,
both end methyldivinylsiloxy-terminated dimethylpolysiloxane,
both end methyldivinylsiloxy-terminated dimethylsiloxane/methylvinylsiloxane copolymers,
both end methyldivinylsiloxy-terminated dimethylsiloxane/diphenylsiloxane copolymers,
both end methyldivinylsiloxy-terminated dimethylsiloxane/methylvinylsiloxane/diphenylsiloxane copolymers,
both end methyldivinylsiloxy-terminated methyltrifluoropropylpolysiloxane,
both end methyldivinylsiloxy-terminated dimethylsiloxane/methyltrifluoropropylsiloxane copolymers,
both end methyldivinylsiloxy-terminated dimethylsiloxane/methyltrifluoropropylsiloxane/methylvinylsiloxane copolymers,
both end trivinylsiloxy-terminated dimethylpolysiloxane,
both end trivinylsiloxy-terminated dimethylsiloxane/methylvinylsiloxane copolymers,
both end trivinylsiloxy-terminated dimethylsiloxane/diphenylsiloxane copolymers,
both end trivinylsiloxy-terminated dimethylsiloxane/methylvinylsiloxane/diphenylsiloxane copolymers,
both end trivinylsiloxy-terminated methyltrifluoropropylpolysiloxane,
both end trivinylsiloxy-terminated dimethylsiloxane/methyltrifluoropropylsiloxane copolymers, and
both end trivinylsiloxy-terminated dimethylsiloxane/methyltrifluoropropylsiloxane/methylvinylsiloxane copolymers.

Although the viscosity of the organopolysiloxane (A) is not particularly limited, it preferably has a viscosity at 25° C. in the range of 50 to 100,000 mPa·s, more preferably 1,000 to 50,000 mPa·s for ease of handling and working of the composition and the strength and flow of cured gel. Notably, the viscosity is measured at 25° C. by a rotational viscometer.

Component (B) functions as a crosslinker by reacting with component (A). It is an organohydrogenpolysiloxane containing at least two silicon-bonded hydrogen atoms (i.e., hydrosilyl or SiH groups) per molecule. The organohydrogenpolysiloxane contains preferably 2 to 30, more preferably 2 to 10, and even more preferably 2 to 5 SiH groups per molecule.

In the organohydrogenpolysiloxane, hydrogen may be attached to the silicon at the end and/or an intermediate position of the molecular chain. Its molecular structure is not particularly limited and may be linear, cyclic, branched or three-dimensional network (or resinous).

In the organohydrogenpolysiloxane, the number of silicon atoms per molecule, that is, average degree of polymerization is typically 20 to 1,000. For ease of handling and working of the composition and better properties (e.g., low modulus and low stress) of cured gel, the number of silicon atoms per molecule is preferably 40 to 1,000, more preferably 40 to 400, even more preferably 60 to 300, further preferably 100 to 300, and most preferably 160 to 300. As used herein, the average degree of polymerization is a weight average degree of polymerization as determined versus polystyrene standards by gel permeation chromatography (GPC) using toluene as solvent.

Typically the organohydrogenpolysiloxane has a viscosity at 25° C. of 10 to 100,000 mPa·s, preferably 200 to 50,000 mPa·s, and more preferably 500 to 25,000 mPa·s. An organohydrogenpolysiloxane which is liquid at room temperature (25° C.) is preferred.

The organohydrogenpolysiloxane preferably has the average compositional formula (2):

R⁴_{c}H_{d}SiO_{(4-c-d)/2} (2)

wherein R⁴ is each independently a substituted or unsubstituted monovalent hydrocarbon group free of aliphatic unsaturation, c is a positive number of 0.7 to 2.2, d is a positive number of 0.001 to 0.5, and the sum c+d is 0.8 to 2.5.

In formula (2), R⁴ is independently a substituted or unsubstituted monovalent hydrocarbon group free of aliphatic unsaturation, having 1 to 10 carbon atoms, preferably 1 to 6 carbon atoms. Examples of the monovalent hydrocarbon group include straight, branched or cyclic alkyl groups such as methyl, ethyl, propyl, isopropyl, butyl, isobutyl, tert-butyl, pentyl, neopentyl, hexyl, cyclohexyl, octyl, nonyl, and decyl; aryl groups such as phenyl, tolyl, xylyl and naphthyl; aralkyl groups such as benzyl, phenylethyl and phenylpropyl; and substituted forms of the foregoing in which some or all hydrogen atoms are substituted by halogen (e.g., chloro, bromo or fluoro) such as 3,3,3-trifluoropropyl. Of these, alkyl, aryl and 3,3,3-trifluoropropyl groups are preferred, and methyl, phenyl and 3,3,3-trifluoropropyl are most preferred.

The subscript c is a positive number of 0.7 to 2.2, preferably 1.0 to 2.1; d is a positive number of 0.001 to 0.5, preferably 0.001 to 0.1, and more preferably 0.005 to 0.1, even more preferably 0.005 to 0.05, and most preferably 0.005 to 0.03; and the sum c+d is in a range of 0.8 to 2.5, preferably 1.0 to 2.5, and more preferably 1.5 to 2.2.

Examples of the organohydrogenpolysiloxane having formula (2) include, but are not limited to, methylhydrogensiloxane/dimethylsiloxane cyclic copolymers, both end trimethylsiloxy-terminated methylhydrogenpolysiloxane, both end trimethylsiloxy-terminated dimethylsiloxane/methylhydrogensiloxane copolymers,

both end dimethylhydrogensiloxy-terminated dimethylpolysiloxane, both end dimethylhydrogensiloxy-terminated dimethylsiloxane/methylhydrogensiloxane copolymers,
both end trimethylsiloxy-terminated methylhydrogensiloxane/diphenylsiloxane copolymers,
both end trimethylsiloxy-terminated methylhydrogen-siloxane/diphenylsiloxane/dimethylsiloxane copolymers,
both end dimethylhydrogensiloxy-terminated methylhydrogen-siloxane/dimethylsiloxane/diphenylsiloxane copolymers, copolymers consisting of (CH₃)₂HSiO_{1/2}, (CH₃)₃SiO_{1/2} and SiO_{4/2} units,
copolymers consisting of (CH₃)₂HSiO_{1/2} and SiO_{4/2} units, and copolymers consisting of (CH₃)₂HSiO_{1/2}, (C₆H₅)SiO_{3/2} and SiO_{4/2} units.

An appropriate amount of component (B) used is at least 1 part, preferably at least 3 parts by weight per 100 parts by weight the component (A). When the upper limit is taken into account, an appropriate amount of component (B) used is 15 to 500 parts, more preferably 20 to 500 parts, and even more preferably 30 to 200 parts by weight per 100 parts by weight the component (A). In addition to the above requirement, component (B) should be used in such amounts as to give 0.3 to 2.5 moles, preferably 0.5 to 2 moles, and more preferably 0.6 to 1.5 moles of silicon-bonded hydrogen per mole of silicon-bonded alkenyl groups in component (A). If the amount of component (B) is less than 1 part by weight, the cured product is likely to oil bleeding. An SiH/alkenyl molar ratio of less than 0.3/1 may provide an insufficient crosslinking density, indicating that the composition may not be fully cured or if cured, the cured product may have poor heat resistance. An SiH/alkenyl molar ratio of more than 2.5/1 may give rise to problems including bubbling due to dehydrogenation reaction, poor heat resistance and oil bleeding of the cured product.

Component (C) is a catalyst for promoting addition reaction between silicon-bonded alkenyl groups in component (A) and silicon-bonded hydrogen atoms (i.e., SiH groups) in component (B). The catalyst is typically a platinum group metal based catalyst which is selected from many well-known catalysts. Examples include platinum black, chloroplatinic acid, alcohol-modified products of chloroplatinic acid, and complexes of chloroplatinic acid with olefins, aldehydes, vinylsiloxanes or acetylene alcohols.

The catalyst is added in a catalytic amount, which may be properly determined depending on the desired cure rate. The catalyst is typically added in such amounts as to give 0.1 to 1,000 ppm, preferably 1 to 300 ppm of platinum atom based on the total weight of components (A) and (B). If the amount of the catalyst is too much, the cured product may have poor heat resistance.

The curable silicone gel composition may be prepared by mixing the foregoing components (A) to (C) and optional components (if used) in a standard way. Upon formulation, the composition may be divided into two or multiple parts, if desired. For example, the composition is divided into one part composed of a portion of component (A) and component (C), and another part composed of the remainder of component (A) and component (B), and these two parts are mixed together on use.

The curable silicone gel composition thus obtained is coated onto one surface of panel 1b which is a transparent member on the sunlight incident side, and cured to form a silicone gel layer 3.

Coating Step

On coating, any of standard techniques such as spray coating, curtain coating, knife coating, screen coating, and combinations thereof may be used. The coating weight is preferably adjusted such that the silicone gel layer 3 as cured may have a thickness of 200 to 1,000 μm, more preferably 300 to 800 μm. If the coating thickness is less than 200 μm, the following problems may arise. The advantageous properties of silicone gel including low modulus and low hardness are not fully available. In the step of pressing the panels with a thin-film solar cell sandwiched therebetween, the coating allows the solar cell to be damaged. In an outdoor environment where temperature fluctuates, the coating fails to accommodate differences in coefficient of linear expansion and modulus from the electrical connection on the solar cell surface, allowing the solar cell to become brittle. If the coating thickness exceeds 1,000 μm, a longer time may be taken for curing and an increased amount of the curable silicone gel composition coated may add to the expense.

Curing Step

After panel 1b is coated with the curable silicone gel composition, it is heat cured at 80 to 150° C. for 5 to 30 minutes in a conventional manner to form a silicone gel layer 3 on panel 1b.

The cured silicone gel film thus formed should preferably have a penetration of 30 to 200, more preferably 40 to 150, as measured according to JIS K2220 using ¼ cone. If the penetration of a coating is less than 30, the following problems may arise. The advantageous properties of cured silicone gel including low modulus and low hardness are not fully available. In the step of pressing the panels with a thin-film solar cell sandwiched therebetween, the coating allows the solar cell to be damaged. In an outdoor environment where temperature fluctuates, the coating fails to accommodate differences in coefficient of linear expansion and modulus from the electrical connection on the solar cell surface, allowing the solar cell to become brittle. If the penetration of a coating exceeds 200, the cured silicone gel may flow, failing to retain its shape.

When one surface of panel 1b is coated with the silicone gel composition, a peripheral region of the panel surface (i.e., silicone gel layer-bearing surface), for example, a peripheral band (like a molding of a picture frame) having a width of 5 to 20 mm should be left uncoated. In the next step, a seal member of water vapor non-permeable, rubber based thermoplastic sealing material, specifically butyl rubber-based thermoplastic sealing material is disposed on this uncoated region. If the silicone gel composition is present, even slightly, on the peripheral region of the panel surface, it adversely affects the adhesion between the seal member and the panel, and moisture can ingress through such defective bonds to threaten the long-term reliability of the solar cell module. Therefore, the peripheral region of the panel surface is masked with masking tape (like a frame molding) before the curable silicone gel composition is coated to the panel surface. Then the composition does not stick to the peripheral region.

(iii) Step of Mating Panels (FIGS. 3 and 4)

Next, as shown in FIG. 3, a seal member 4 of butyl rubber-based thermoplastic sealing material which is thicker than the silicone gel layer 3 is provided on the peripheral region of the silicone gel layer-bearing surface of panel 1b where the silicone gel layer 3 is not formed.

The seal member 4 is made of a butyl rubber-based thermoplastic sealing material, which may be any of commercially available butyl rubber-based sealing materials. Since the subsequent step of vacuum lamination applies heat at a temperature of 100 to 150° C., a sealing material of hot melt type capable of retaining its shape in that temperature range is preferred. A suitable hot melt sealing material is available under the trade name Hot Melt M-155P (adhesive for solar modules) from Yokohama Rubber Co., Ltd.

The seal member 4 may be provided by any desired ways. Using a hot-melt applicator, for example, the butyl rubber-based thermoplastic sealing material is coated to the peripheral region of the silicone gel layer-bearing surface of panel 1b where the silicone gel layer 3 is not formed. Alternatively, the butyl rubber-based thermoplastic sealing material is previously shaped as a piece of tape or strip, which is extended on the peripheral region.

Next, as shown in FIG. 4, the one and other panels 1a and 1b are mated or joined together such that the thin-film solar cell-bearing surface of panel 1a may be opposed to the silicone gel layer-bearing surface of panel 1b, the silicone gel layer 3 may overlap the thin-film solar cell 2, and the seal member 4 may be sandwiched between the peripheral region of panel 1a where the thin-film solar cell 2 is not formed and the peripheral region of panel 1b where the silicone gel layer 3 is not formed. At this point, the panel 1a is physically supported by the seal member 4, but a gap is left between the panel 1a and the seal member 4 that can provide fluid communication between the exterior of panel 1a and any space between panels 1a and 1b. The thin-film solar cell 2 on panel 1a is spaced apart from the silicone gel layer 3 on panel 1b so that the space between the thin-film solar cell 2 and the silicone gel layer 3 may be evacuated when a vacuum laminator is vacuum operated. This mating step may be carried out within the confines of a vacuum laminator to be described later.

It is noted that the mating step may be modified as follows. The seal member 4 is placed on the peripheral region of panel 1a where the thin-film solar cell 2 is not formed. Thereafter, the panels 1a and 1b are mated together such that the silicone gel layer-bearing surface of panel 1b may be opposed to the thin-film solar cell-bearing surface of panel 1a, the silicone gel layer 3 may overlap the thin-film solar cell 2, and the seal member 4 may be sandwiched between the peripheral region of panel 1a where the thin-film solar cell 2 is not formed and the peripheral region of panel 1b where the silicone gel layer 3 is not formed.

### (iv) Step of Vacuum Lamination (FIG. 5)

Next, the precursory laminate or assembly of two panels 1a, 1b as shown in FIG. 4 is vacuum laminated. Specifically, using a vacuum laminator (not shown), two panels 1a, 1b are pressed together while heating in vacuum, for thereby sealing the thin-film solar cell 2, as shown in FIG. 5.

The vacuum laminator used herein may be a laminator comprising two adjacent vacuum tanks partitioned by a flexible membrane, as commonly used in the manufacture of solar cell modules. For example, the precursory assembly of panels 1a, 1b as shown in FIG. 4 is set in one tank, two tanks are pumped to vacuum, so that a substantial vacuum is established between panels 1a and 1b. At the same time, at least outer portions of panels 1a, 1b are heated. Thereafter, while the one tank having the precursory assembly of panels 1a, 1b set therein is kept in vacuum, the other tank is released to atmospheric pressure or even kept under an applied pressure, whereby the panels 1a, 1b are compressed in their thickness direction by the membrane. For example, the panels 1a, 1b are compressed for 1 to 5 minutes while heating at 100 to 150° C. Then the seal member 4 is tightly bonded to panels 1a, 1b.

Since the silicone gel layer 3 is pressed to the thin-film solar cell 2 in vacuum and between the panels 1a and 1b, the thin-film solar cell 2 is closely covered with the silicone gel layer 3 without trapping air bubbles therebetween. Since the silicone gel layer 3 typically has a substantial penetration, the thin-film solar cell 2 is sealed between the silicone gel layer 3 and panel 1a without damages. Since a pressure acting in a direction to press panels 1a, 1b is applied to the seal member 4 which is heated at the predetermined temperature, the seal member 4 tightly seals the peripheral region of the surface of panels 1a, 1b and the peripheral edges of the silicone gel layer 3 and becomes a seal portion 4′ bonded to the panels 1a, 1b. As a result, the seal portion 4′ tightly encloses the silicone gel layer 3 and thin-film solar cell 2 together with two panels 1a, 1b, preventing the ingress of moisture and gas into the solar cell module from its edge faces. The resulting solar cell module is thus of fully durable performance.

Another method is possible for manufacturing the solar cell module of the first embodiment. The other method is defined as comprising the steps of:

(i) stacking a metal electrode layer, a photoelectric conversion layer, and a light-transmissive electrode layer on one surface of a first substrate (panel 1a), excluding a peripheral region of the one surface, in the described order to construct a thin-film solar cell (thin-film solar cell 2),

(ii) providing a transparent second substrate (panel 1b) having a surface and a light-transmissive silicone gel sheet which is smaller than the surface of the second substrate and larger than the thin-film solar cell,

(iii) mating the first and second substrates together while placing the silicone gel sheet between the thin-film solar cell-bearing surface of the first substrate and the surface of the second substrate and above the thin-film solar cell, and placing a seal member (seal member 4) between the peripheral region of the first substrate where the thin-film solar cell is not formed and a peripheral region of the second substrate which does not overlap the silicone gel sheet, the seal member comprising a water vapor non-permeable, rubber-based thermoplastic sealing material and being thicker than the silicone gel sheet, and

(iv) compressing and heating the first and/or second substrate in the mated state for establishing a seal around the thin-film solar cell.

The silicone gel sheet used in step (ii) may be a sheet obtained by coating and curing the silicone gel composition defined herein onto a support. More particularly, the support may be a flexible thin sheet such as polyethylene terephthalate film, polypropylene film, paper, or fabric, typically supplied in roll form. Using a suitable applicator, the silicone gel composition is continuously applied to the support. The applicator may be any well-known apparatus such as a comma coater, reverse coater, bar coater or die coater. After the silicone gel composition is applied to the support by the applicator, the composition is heat cured at 100 to 300° C. for about 5 minutes, yielding a silicone gel sheet. The heating temperature is preferably in a range of 120 to 200° C. If a protective sheet is attached to the surface of the silicone gel sheet remote from the support, the silicone gel sheet is protected and becomes easy to handle. Like the support, the protective sheet may be a flexible thin sheet such as polyethylene terephthalate film, polypropylene film, paper, or fabric. The thickness and penetration of the silicone gel sheet may be the same as the silicone gel layer 3 which is formed by directly coating the silicone gel composition to panel 1b.

The size of the silicone gel sheet is smaller than the surface of panel 1b enough to leave a peripheral region of panel 1b where the seal member 4 is placed and larger than the thin-film solar cell 2 enough to overlap the overall thin-film solar cell 2.

In a preferred embodiment, step (iii) includes attaching a silicone gel sheet preformed as above to the second substrate (panel 1b), prior to the mating of the first and second substrates (panels 1a and 1b). More particularly, the protective sheet/silicone gel sheet/support assembly is used. The protective sheet is peeled from the silicone gel sheet, the bare surface of the silicone gel sheet is attached to the panel 1b in alignment, and the support is peeled from the silicone gel sheet. This results in the same state as the silicone gel layer 3 in FIG. 2. In a preferred procedure, after the silicone gel sheet is attached to panel 1b, the surface of the silicone gel sheet is activated by plasma irradiation or excimer light irradiation, and the vacuum lamination step is then carried out. This procedure improves the bond of the silicone gel sheet to the thin-film solar cell 2 and panel 1a.

### Second Embodiment

A second embodiment of the invention is a solar cell module comprising a transparent first substrate (panel 1a) having a surface, a thin-film solar cell (thin-film solar cell 2) comprising a light-transmissive electrode layer, a photoelectric conversion layer, and a metal electrode layer disposed on the surface of the first substrate in the described order, a second substrate (panel 1b) disposed above the surface of the first substrate, a silicone gel layer (silicone gel layer 3) interposed between the first and second substrates so as to overlap the thin-film solar cell, and a seal portion (seal portion 4′) comprising a water vapor non-permeable, rubber-based thermoplastic sealing material surrounding and sealing the outer periphery of the silicone gel layer.

The second embodiment differs from the first embodiment in that panel 1a is a transparent substrate (that is, identical with panel 1b in the first embodiment), that the layer structure of the thin-film solar cell 2 formed on panel 1a has a sequence of light-transmissive electrode layer, photoelectric conversion layer, and metal electrode layer from panel 1a side, reverse to the first embodiment, and that panel 1b need not necessarily be light-transmissive or transparent (that is, identical with panel 1a in the first embodiment). Otherwise, the second embodiment is identical with the first embodiment.

A method for manufacturing the solar cell module of the second embodiment is the same as the first embodiment except the differences pointed out above. Referring to FIGS. 1 to 5, a method for manufacturing the solar cell module of the second embodiment is defined as comprising the steps of:

(i) stacking a light-transmissive electrode layer, a photoelectric conversion layer, and a metal electrode layer on one surface of a transparent first substrate (panel 1a), excluding a peripheral region of the one surface, in the described order to construct a thin-film solar cell (thin-film solar cell 2) as shown in FIG. 1,

(ii) forming a silicone gel layer (silicone gel layer 3) on one surface of a second substrate (panel 1b), excluding a peripheral region of the one surface, as shown in FIG. 2,

(iii) mating the first and second substrates together such that the thin-film solar cell-bearing surface of the first substrate may be opposed to the silicone gel layer-bearing surface of the second substrate, and the silicone gel layer may overlap the thin-film solar cell, while interposing a seal member (seal member 4) between the peripheral region of the first substrate where the thin-film solar cell is not formed and the peripheral region of the second substrate where the silicone gel layer is not formed, the seal member comprising a water vapor non-permeable, rubber-based thermoplastic sealing material and being thicker than the silicone gel layer, as shown in FIGS. 3 and 4, and

(iv) compressing and heating the first and/or second substrate in the mated state for establishing a seal around the thin-film solar cell as shown in FIG. 5.

Another method for manufacturing the solar cell module of the second embodiment is the same as in the first embodiment except the differences pointed out above. The other method is defined as comprising the steps of:

(i) stacking a light-transmissive electrode layer, a photoelectric conversion layer, and a metal electrode layer on one surface of a transparent first substrate (panel 1a), excluding a peripheral region of the one surface, in the described order to construct a thin-film solar cell (thin-film solar cell 2) as shown in FIG. 1,

(ii) providing a second substrate (panel 1b) having a surface and a silicone gel sheet which is smaller than the surface of the second substrate and larger than the thin-film solar cell,

(iii) mating the first and second substrates together while placing the silicone gel sheet between the thin-film solar cell-bearing surface of the first substrate and the surface of the second substrate and above the thin-film solar cell, and placing a seal member (seal member 4) between the peripheral region of the first substrate where the thin-film solar cell is not formed and a peripheral region of the second substrate which does not overlap the silicone gel sheet, the seal member comprising a water vapor non-permeable, rubber-based thermoplastic sealing material and being thicker than the silicone gel sheet, as shown in FIGS. 3 and 4, and

(iv) compressing and heating the first and/or second substrate in the mated state for establishing a seal around the thin-film solar cell as shown in FIG. 5.

Like the first embodiment, the second embodiment ensures that the seal portion 4′ of water vapor non-permeable, rubber-based thermoplastic sealing material tightly encloses the inside silicone gel layer 3 and thin-film solar cell 2 together with two panels 1a, 1b, preventing the ingress of moisture and gas into the solar cell module from its edge faces. The resulting solar cell module is thus of fully durable performance.

### EXAMPLE

Examples of the invention are given below by way of illustration and not by way of limitation. With respect to the silicone gel composition, the viscosity is measured at 25° C. by a rotational viscometer; all parts and percents are by weight; and Vi stands for vinyl.

### Example 1

There was furnished a first substrate or soda-lime glass plate of 1.8 mm thick and 22 cm squares. After a peripheral region of the first substrate was masked with a metal mask, constituent layers of a thin-film solar cell were deposited only on the inside region of 21 cm squares of the first substrate. Specifically, the first substrate was cleaned and the mask was laid on its surface. By the DC magnetron sputtering method, a Mo electrode film was deposited to a thickness of 0.8 μm. Then a CIGS layer of 2 μm thick was deposited by the three-stage evaporation method, a CdS buffer layer of 50 to 100 nm thick was deposited by the solution growth method, and a ZnO semi-insulating layer and an Al-doped ZnO transparent electrode layer were deposited by the sputtering method to a total thickness of 0.7 μm. Further, a MgF₂ film of 120 nm thick was deposited by the vacuum evaporation method as antireflective film. An Al/Ni layer was formed by the vacuum evaporation method and processed to form an interdigitated electrode and extracting electrode on the thin-film solar cell. A tab for electrode lead-out was solder connected to the extracting electrode.

There was furnished a second substrate or soda-lime glass plate of the same size (1.8 mm thick and 22 cm squares) as the first substrate. With a peripheral region of 7 mm wide of the second substrate masked, a silicone gel composition was coated to the inside region and heat cured in an oven at 150° C. for 30 minutes, forming a silicone gel layer.

The silicone gel composition was prepared by mixing 100 parts of both end dimethylvinylsiloxy-terminated dimethylpolysiloxane having a viscosity of 1,000 mPa·s, 63 parts of both end trimethylsiloxy-terminated dimethylsiloxane/methylhydrogensiloxane copolymer represented by the formula (3) and having a viscosity of 1,000 mPa·s (to give 1.05 silicon-bonded hydrogen in component (B) per silicon-bonded alkenyl in component (A), that is, H/Vi ratio=1.05), and 0.05 part of a dimethylpolysiloxane solution of chloroplatinic acid-vinylsiloxane complex (platinum concentration 1%) until uniform.

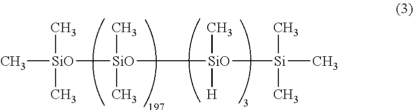

When the composition was cured in an oven at 150° C. for 30 minutes, the cured gel product had a penetration of 70. It is noted that the penetration was measured according to JIS K2220 with a ¼ cone, using an automatic penetrometer RPM-101 by Rigo Co., Ltd.

A high-temperature butyl rubber having a high melting temperature was worked into a strip of 2 mm high, which was extended along the peripheral region of 7 mm wide of the second substrate surface where the silicone gel layer was not formed.

Next, the first substrate was rested on the second substrate, with the thin-film solar cell-bearing surface of the first substrate faced downward to the silicone gel layer-bearing surface of the second substrate. Using a vacuum laminator, the substrates were pressed at 130° C. for 10 minutes, completing a solar cell module.

### Comparative Example 1

Example 1 was changed. There was furnished a second substrate or soda-lime glass plate of the same size (1.8 mm thick and 22 cm squares) as the first substrate. The first substrate was rested on the second substrate while an EVA sheet of 0.7 mm thick was interposed between the second substrate and the thin-film solar cell-bearing surface of the first substrate. Using a vacuum laminator, the substrates were pressed at 130° C. for 20 minutes, completing a comparative solar cell module.

The solar cell modules of Example 1 and Comparative Example 1 were placed in a high temperature/high humidity tank and tested at 85° C. and RH 85% for 2,000 hours. The solar cell module of Example 1 experienced an output drop of 4% relative to the initial solar cell performance whereas the solar cell module of Comparative Example 1 experienced a large output drop of 20%, indicating substantial degradation.

Japanese Patent Application No. 2013-135864 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A solar cell module comprising
a first substrate having a surface,
a thin-film solar cell comprising a metal electrode layer, a photoelectric conversion layer, and a light-transmissive electrode layer disposed on the surface of the first substrate in the described order,
a transparent second substrate disposed above the surface of the first substrate,
a light-transmissive silicone gel layer interposed between the first and second substrates so as to overlap the thin-film solar cell, and
a seal portion comprising a water vapor non-permeable, rubber-based thermoplastic sealing material surrounding and sealing the outer periphery of the silicone gel layer.

2. A solar cell module comprising
a transparent first substrate having a surface,
a thin-film solar cell comprising a light-transmissive electrode layer, a photoelectric conversion layer, and a metal electrode layer disposed on the surface of the first substrate in the described order,
a second substrate disposed above the surface of the first substrate,
a silicone gel layer interposed between the first and second substrates so as to overlap the thin-film solar cell, and
a seal portion comprising a water vapor non-permeable, rubber-based thermoplastic sealing material surrounding and sealing the outer periphery of the silicone gel layer.

3. The solar cell module of claim 1 wherein the rubber-based thermoplastic sealing material is butyl rubber.

4. The solar cell module of claim 1 wherein the photoelectric conversion layer comprises a chalcopyrite compound semiconductor.

5. The solar cell module of claim 1 wherein the photoelectric conversion layer comprises a chalcogen compound semiconductor.

6. The solar cell module of claim 1 wherein the photoelectric conversion layer is an amorphous silicon layer.

7. The solar cell module of claim 1 wherein the photoelectric conversion layer is a microcrystalline thin-film silicon layer.

8. The solar cell module of claim 1 wherein the photoelectric conversion layer is a germanium-containing thin-film layer.

9. A method for manufacturing a solar cell module comprising the steps of:
(i) stacking a metal electrode layer, a photoelectric conversion layer, and a light-transmissive electrode layer on one surface of a first substrate, excluding a peripheral region of the one surface, in the described order to construct a thin-film solar cell,
(ii) forming a light-transmissive silicone gel layer on one surface of a transparent second substrate, excluding a peripheral region of the one surface,
(iii) mating the first and second substrates together such that the thin-film solar cell-bearing surface of the first substrate may be opposed to the silicone gel layer-bearing surface of the second substrate, and the silicone gel layer may overlap the thin-film solar cell, while interposing a seal member between the peripheral region of the first substrate where the thin-film solar cell is not formed and the peripheral region of the second substrate where the silicone gel layer is not formed, the seal member comprising a water vapor non-permeable, rubber-based thermoplastic sealing material and being thicker than the silicone gel layer, and
(iv) compressing and heating the first and/or second substrate in the mated state for establishing a seal around the thin-film solar cell.

10. A method for manufacturing a solar cell module comprising the steps of:
(i) stacking a metal electrode layer, a photoelectric conversion layer, and a light-transmissive electrode layer on one surface of a first substrate, excluding a peripheral region of the one surface, in the described order to construct a thin-film solar cell,
(ii) providing a transparent second substrate having a surface and a light-transmissive silicone gel sheet which is smaller than the surface of the second substrate and larger than the thin-film solar cell,
(iii) mating the first and second substrates together while placing the silicone gel sheet between the thin-film solar cell-bearing surface of the first substrate and the surface of the second substrate and above the thin-film solar cell, and placing a seal member between the peripheral region of the first substrate where the thin-film solar cell is not formed and a peripheral region of the second substrate which does not overlap the silicone gel sheet, the seal member comprising a water vapor non-permeable, rubber-based thermoplastic sealing material and being thicker than the silicone gel sheet, and
(iv) compressing and heating the first and/or second substrate in the mated state for establishing a seal around the thin-film solar cell.

11. A method for manufacturing a solar cell module comprising the steps of:
(i) stacking a light-transmissive electrode layer, a photoelectric conversion layer, and a metal electrode layer on one surface of a transparent first substrate, excluding a peripheral region of the one surface, in the described order to construct a thin-film solar cell,
(ii) forming a silicone gel layer on one surface of a second substrate, excluding a peripheral region of the one surface,
(iii) mating the first and second substrates together such that the thin-film solar cell-bearing surface of the first substrate may be opposed to the silicone gel layer-bearing surface of the second substrate, and the silicone gel layer may overlap the thin-film solar cell, while interposing a seal member between the peripheral region of the first substrate where the thin-film solar cell is not formed and the peripheral region of the second substrate where the silicone gel layer is not formed, the seal member comprising a water vapor non-permeable, rubber-based thermoplastic sealing material and being thicker than the silicone gel layer, and
(iv) compressing and heating the first and/or second substrate in the mated state for establishing a seal around the thin-film solar cell.

12. A method for manufacturing a solar cell module comprising the steps of:
(i) stacking a light-transmissive electrode layer, a photoelectric conversion layer, and a metal electrode layer on one surface of a transparent first substrate, excluding a peripheral region of the one surface, in the described order to construct a thin-film solar cell,
(ii) providing a second substrate having a surface and a silicone gel sheet which is smaller than the surface of the second substrate and larger than the thin-film solar cell,
(iii) mating the first and second substrates together while placing the silicone gel sheet between the thin-film solar cell-bearing surface of the first substrate and the surface of the second substrate and above the thin-film solar cell, and placing a seal member between the peripheral region of the first substrate where the thin-film solar cell is not formed and a peripheral region of the second substrate which does not overlap the silicone gel sheet, the seal member comprising a water vapor non-permeable, rubber-based thermoplastic sealing material and being thicker than the silicone gel sheet, and
(iv) compressing and heating the first and/or second substrate in the mated state for completing a seal around the thin-film solar cell.

13. The method of claim 9 wherein step (i) includes applying a curable silicone gel composition on the one surface of the second substrate and curing it to form a silicone gel layer.

14. The method of claim 10 wherein step (iii) includes attaching the preformed silicone gel sheet to the second substrate, prior to the mating of the first and second substrates.

15. The method of claim 9 wherein the seal member is made of butyl rubber.

16. The method of claim 9 wherein includes placing the mated first and second substrates in a space, evacuating the space to vacuum, and heating and compressing the first and second substrates in vacuum for establishing a seal around the thin-film solar cell.

17. The solar cell module of claim 2 wherein the rubber-based thermoplastic sealing material is butyl rubber.

18. The solar cell module of claim 2 wherein the photoelectric conversion layer comprises a chalcopyrite compound semiconductor.

19. The solar cell module of claim 2 wherein the photoelectric conversion layer comprises a chalcogen compound semiconductor.

20. The solar cell module of claim 2 wherein the photoelectric conversion layer is an amorphous silicon layer.

21. The solar cell module of claim 2 wherein the photoelectric conversion layer is a microcrystalline thin-film silicon layer.

22. The solar cell module of claim 2 wherein the photoelectric conversion layer is a germanium-containing thin-film layer.

23. The method of claim 11 wherein step (i) includes applying a curable silicone gel composition on the one surface of the second substrate and curing it to form a silicone gel layer.

24. The method of claim 12 wherein step (iii) includes attaching the preformed silicone gel sheet to the second substrate, prior to the mating of the first and second substrates.

25. The method of claim 10 wherein the seal member is made of butyl rubber.

26. The method of claim 11 wherein the seal member is made of butyl rubber.

27. The method of claim 12 wherein the seal member is made of butyl rubber.

28. The method of claim 10 wherein includes placing the mated first and second substrates in a space, evacuating the space to vacuum, and heating and compressing the first and second substrates in vacuum for establishing a seal around the thin-film solar cell.

29. The method of claim 11 wherein includes placing the mated first and second substrates in a space, evacuating the space to vacuum, and heating and compressing the first and second substrates in vacuum for establishing a seal around the thin-film solar cell.

30. The method of claim 12 wherein includes placing the mated first and second substrates in a space, evacuating the space to vacuum, and heating and compressing the first and second substrates in vacuum for establishing a seal around the thin-film solar cell.
